(19) United States
(12) Patent Application Publication
(10) Pub. No.: US 2026/0169375 A1
(43) Pub. Date: Jun. 18, 2026

(54) IMPRINT DEVICE, IMPRINTING METHOD, AND METHOD OF MANUFACTURING SEMICONDUCTOR DEVICE

(71) Applicant: Kioxia Corporation, Tokyo (JP)

(72) Inventors: Ryutaro OTAHARA, Yokkaichi Mie (JP); Shuichi TANIGUCHI, Yokohama Kanagawa (JP); Yukichi KAMITA, Yokkaichi Mie (JP); Kyo OTSUBO, Yokkaichi Mie (JP); Masayuki HATANO, Yokkaichi Mie (JP)

(73) Assignee: Kioxia Corporation, Tokyo (JP)

(21) Appl. No.: 19/232,995

(22) Filed: Jun. 10, 2025

(30) Foreign Application Priority Data
Dec. 17, 2024 (JP) 2024-220566

(51) Int. Cl. G03F 7/00; G03F 7/16

(52) U.S. Cl. CPC G03F 7/0002; G03F 7/161; G03F 7/70908

(57) ABSTRACT

An imprint device according to the embodiment performs an imprinting process. The imprinting process includes forming a resin film on a substrate having a plurality of shot regions and forming a pattern by pressing a template against the resin film. The imprint device includes a computer that controls the imprinting process. The computer changes a residual layer thickness based on a particle size of a foreign substance existing on the substrate. The residual layer thickness is a thickness of the resin film at a bottom face of a recessed part in the pattern.

### CROSS-REFERENCE TO RELATED APPLICATIONS

This application is based upon and claims the benefit of priority from Japanese Patent Application No. 2024-220566, filed on Dec. 17, 2024, the entire contents of which are incorporated herein by reference.

### FIELD

The embodiments described herein relate generally to an imprint device, an imprinting method, and a method of manufacturing a semiconductor device.

### BACKGROUND

The imprinting process is used in a process of manufacturing a semiconductor device. In the imprinting process, a template on which the pattern is formed is pressed against a substrate of the semiconductor device. At this time, the template may be damaged when there is a foreign substance on the substrate.

### BRIEF DESCRIPTION OF THE DRAWINGS

FIGS. 1A to 1C are schematic diagrams illustrating an example of a configuration of a template according to the embodiment;

FIGS. 2A and 2B are schematic diagrams illustrating an example of a configuration of a substrate according to the embodiment;

FIG. 3 is a schematic diagram illustrating a configuration example of an imprint device according to the embodiment;

FIG. 4 is a diagram illustrating an example of a layout of a plurality of templates according to the embodiment;

FIGS. 5A to 5C are diagrams for describing an operation example of the imprint device in the imprinting process according to the embodiment;

FIG. 6 is a diagram illustrating correlation data representing the relationship between the particle size of the foreign substance and the minimum residual layer thickness necessary for suppressing damage of the template;

FIGS. 7A to 7C are diagrams illustrating a shot region and a corresponding template disposed side by side according to the embodiment; and

FIG. 8 is a flowchart illustrating a procedure of an imprinting process executed by the imprint device according to the embodiment.

### DETAILED DESCRIPTION

An imprint device according to the embodiment performs an imprinting process. The imprinting process include forming a resin film on a substrate having a plurality of shot regions and forming a pattern by pressing a template against the resin film. The imprint device includes a computer that controls the imprinting process. The computer is configured to change a residual layer thickness based on a particle size of a foreign substance existing on the substrate. The residual layer thickness is a thickness of the resin film at a bottom face of a recessed part in the pattern.

Hereinafter, embodiments will be described in detail with reference to the drawings. In addition, the present invention is not limited by the following embodiment. In addition, constituent elements in the following embodiments include those that can be easily assumed by those skilled in the art or those that are substantially the same.

### (Configuration Example of Template and Wafer)

In the imprinting process, the pattern of the template is transferred to the resist by a pressing operation of pressing the template, on which the fine pattern is formed, against the resist on the substrate. The resist is an example of a resin film disposed on a substrate for forming a pattern on the substrate.

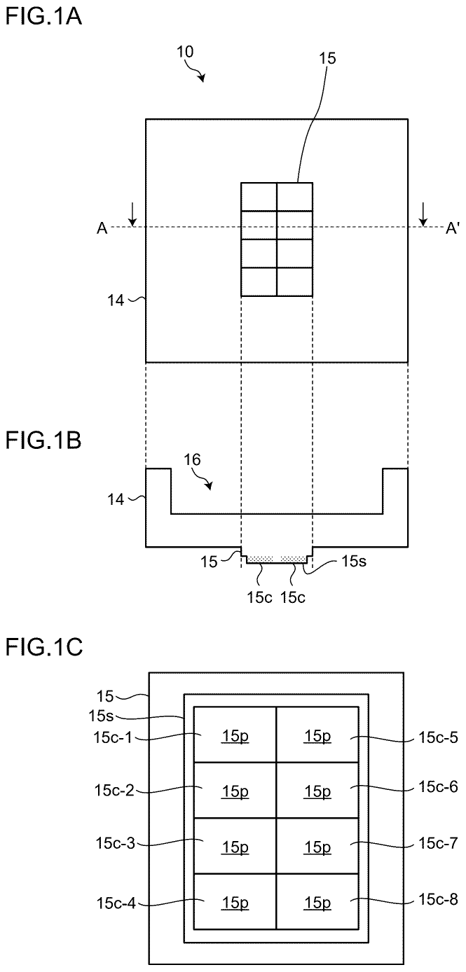

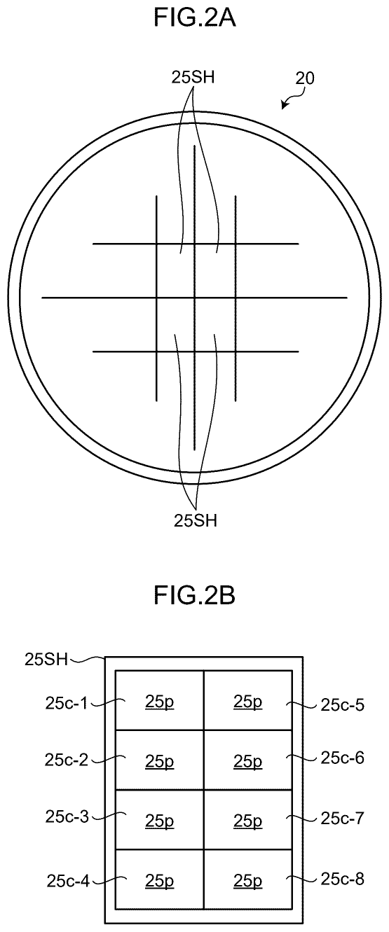

Hereinafter, configurations of a template 10 and a substrate 20 according to the embodiment will be described with reference to FIGS. 1A to 2B.

FIGS. 1A to 1C are schematic diagrams illustrating an example of a configuration of a template 10 according to an embodiment. FIG. 1A is a plan view of the template 10, FIG. 1B is a cross-sectional view taken along line A-A′ of FIG. 1A, and FIG. 1C is a partially enlarged view of a mesa portion 15 of FIG. 1A. Note that, in FIG. 1B, hatching is omitted in consideration of visibility.

The template 10 is made of a transparent member such as quartz glass. As illustrated in FIGS. 1A and 1B, the template 10 includes, for example, a rectangular template substrate 14. The mesa portion 15 is provided on the front face of the template substrate 14, and a counterbore 16 is provided on the back face.

The mesa portion 15 is disposed at a central part of the template substrate 14 and has, for example, a rectangular shape. The mesa portion 15 has a transfer face 15s that is pressed against the resist on the substrate 20 in one pressing operation.

As illustrated in FIG. 1C, the transfer face 15s has, for example, eight chip pattern regions 15c-1 to 15c-8 in each of which a fine pattern 15p having a nano-order size is formed. The fine pattern 15p can be, for example, a pattern in which a plurality of grooves is disposed, a pattern in which a plurality of dots is disposed, or the like. The transfer face 15s may have a mark or the like for alignment.

The configuration of the template 10 illustrated in FIGS. 1A to 1C is one example, and the present invention is not limited thereto. The number and arrangement of the chip pattern regions 15c are optional.

Hereinafter, in a case where the chip pattern regions 15c-1 to 15c-8 are not individually distinguished, the chip pattern regions 15c-1 to 15c-8 may be referred to as a chip pattern region 15c.

FIGS. 2A and 2B are schematic diagrams illustrating an example of a configuration of the substrate 20 according to the embodiment. FIG. 2A is a plan view of the substrate 20, and FIG. 2B is a partially enlarged view of a shot region 25SH in FIG. 2A.

As illustrated in FIG. 2A, the upper face of the substrate 20 is partitioned into a plurality of shot regions 25SH. The plurality of shot regions 25SH is disposed in a lattice pattern on substantially the entire face of the substrate 20. The shot region 25SH is a region to be a processing unit per one time in some processes including the imprinting process among processes of manufacturing the semiconductor device. In the imprinting process, the transfer face 15s of the template 10 is pressed against each shot region 25SH.

As illustrated in FIG. 2B, chip regions 25c-1 to 25c-8 are provided in each of the shot regions 25SH. The chip regions 25c-1 to 25c-8 are regions to be cut out into chips at the end of the process of manufacturing the semiconductor device. In each of the chip regions 25c-1 to 25c-8, an element portion 25p is provided. A mark or the like for alignment may be added outside the element portion 25p.

In a state where the substrate 20 and the template 10 are aligned, the chip regions 25c-1 to 25c-8 are disposed at positions that fit within the transfer face 15s of the template 10. One chip region 25c of the substrate 20 is a region substantially equal to one chip pattern region 15c of the template 10. Then, the fine pattern 15p of the chip pattern region 15c is transferred to the element portion 25p of the chip region 25c by one pressing operation. The element portion 25p of the chip region 25c is disposed at a position facing the fine pattern 15p of the chip pattern region 15c.

Note that the configuration of the substrate 20 illustrated in FIGS. 2A and 2B is one example, and the present invention is not limited thereto. The configuration of the substrate 20 can be changed together with the configuration of the template 10.

Hereinafter, in a case where the chip regions 25c-1 to 25c-8 are not individually distinguished, each of the chip regions 25c-1 to 25c-8 may be referred to as a chip region 25c.

### (Configuration Example of Imprint Device 1)

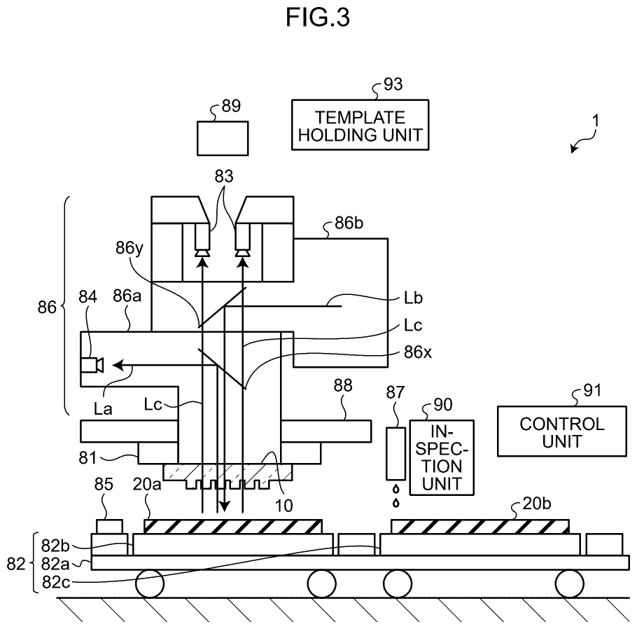

FIG. 3 is a schematic diagram illustrating a configuration example of an imprint device 1 according to the embodiment.

As illustrated in FIG. 3, the imprint device 1 includes a template stage 81, a wafer stage 82, imaging elements 83 and 84, a reference mark 85, an alignment unit 86, a liquid dropping device 87, a stage base 88, a light source 89, an inspection unit 90, a control unit 91, and a template storage unit 93. The template 10 is attached to the imprint device 1.

The wafer stage 82 includes wafer chucks 82b and 82c and a main body 82a. Substrates 20a and 20b to be imprinted are placed on the wafer chucks 82b and 82c, respectively. The substrates 20a and 20b may be a semiconductor substrate including a silicon wafer, an insulating substrate, a conductive substrate, or the like. The substrate 20b is a substrate to be imprinted next to the substrate 20a.

The wafer chucks 82b and 82c are disposed adjacent to each other on the main body 82a of the wafer stage 82, and are configured as suction chucks that suck the substrates 20a and 20b to suck the substrates to predetermined positions on the main body 82a.

The reference mark 85 is provided on the wafer stage 82. The reference mark 85 is used for alignment when the substrate 20a or 20b is loaded on the wafer stage 82.

The wafer stage 82 on which the substrates 20a and 20b are placed moves in parallel planes (horizontal planes). The wafer stage 82 moves each of the substrates 20a and 20b under the inspection unit 90 or the liquid dropping device 87 when foreign substance inspection of the substrates 20a and 20b is performed and when resist is dropped on the substrates 20a and 20b. When the imprinting process on the substrates 20a and 20b is performed, the wafer stage 82 moves each of the substrates 20a and 20b under the template 10.

Hereinafter, in a case where the substrates 20a and 20b are not individually distinguished, the substrates 20a and 20b may be referred to as a substrate 20.

The stage base 88 supports the template 10 by the template stage 81 and moves in the up-down direction (vertical direction). This enables the pressing operation.

The alignment unit 86 including a plurality of imaging elements 83 is provided on the stage base 88. The alignment unit 86 detects the position of the substrate 20 and the position of the template 10 based on the alignment marks provided on the substrate 20 and the template 10, respectively.

The alignment unit 86 includes a detection system 86a and an illumination system 86b. The illumination system 86b applies light to the substrate 20 and the template 10 to make alignment marks formed on them visible. The detection system 86a detects the images of the alignment marks and aligns the positions of the marks to align each of the substrates 20 and the template 10.

The detection system 86a and the illumination system 86b include mirrors 86x and 86y, respectively, such as dichroic mirrors as image forming units. The mirrors 86x and 86y form images from the substrate 20 and the template 10 such as alignment marks by light from the illumination system 86b.

Specifically, the light Lb from the illumination system 86b is reflected downward to a place where the substrate 20 is disposed by the mirror 86y. The light La from the substrate 20 is reflected by the mirror 86x toward the detection system 86a. Part of the light Lc from the substrate 20 and the like passes through the mirrors 86x and 86y and travels upward toward the imaging element 83.

The imaging element 83 captures the part of the light Lc as an image including an alignment mark and the like. The image captured by the imaging element 83 is analyzed by the control unit 91 in order to align the substrate 20 and the template 10.

The light La reflected toward the detection system 86a by the mirror 86x travels toward the imaging element 84 included in the detection system 86a.

The imaging element 84 captures the light La reflected by the mirror 86x as an image including an alignment mark and the like. The image captured by the imaging element 84 is analyzed by the control unit 91 in order to align the substrate 20 and the template 10.

The liquid dropping device 87 is a device that drops a resist on the substrate 20 by an inkjet method. The inkjet head included in the liquid dropping device 87 has a plurality of fine holes for ejecting the droplets of the resist, and drops the droplets of the resist to each shot region 25SH on the substrate 20 based on the drop recipe generated in the control unit 91.

The light source 89 is, for example, a device that emits light such as ultraviolet light for curing the resist. The light source 89 is provided above the stage base 88. The light source 89 emits light from above the template 10 while the template 10 is pressed against the resist.

The inspection unit 90 is a foreign substance inspection device that irradiates the substrate 20 placed on the wafer stage 82 with a laser or the like and inspects a foreign substance on the substrate 20 based on the intensity of scattered light. The inspection unit 90 inspects the presence or absence of the foreign substance on substantially the entire face of the substrate 20 before the resist is dropped to output inspection data. The inspection data includes information about the particle size of the foreign substance existing on the substrate 20 and position information of the foreign substance. The position information of the foreign substance is, for example, the shot region 25SH where the foreign substance exists, the chip region 25c where the foreign substance exists, coordinates of the foreign substance on the substrate 20, etc. The inspection data is analyzed by the control unit 91 to create a drop recipe. The particle size of the foreign substance is an example of the size of the foreign substance. The particle size is, for example, a diameter of a foreign substance. The detection unit 90 may be provided outside the imprint device 1.

The control unit 91 is configured as a computer that includes, for example, a hardware processor such as a central processing unit (CPU), a memory, a hard disk drive (HDD), and the like. The control unit 91 controls an imprinting process including first and second control processes to be described later in accordance with a computer program. The control unit 91 executes the imprinting process by controlling the template stage 81, the wafer stage 82, the reference mark 85, the alignment unit 86 including the imaging elements 83 and 84, the liquid dropping device 87, the stage base 88, the light source 89, the inspection unit 90, and the template storage unit 93.

The memory of the control unit 91 stores, for example, a computer program executed by the CPU of the control unit 91, various control parameters necessary for the operation of the CPU, and the like. The HDD of the control unit 91 stores, for example, a plurality of templates 10 held in the template storage unit 93 and various kinds of information related to the substrate 20. The various kinds of information include, for example, design data including layout information of each of the templates 10, design data of the substrate 20, and inspection data of the substrate 20 output from the inspection unit 90.

The template storage unit 93 stores a plurality of templates 10 attachable to the imprint device 1. The template storage unit 93 determines the template 10 selected by the control unit 91 from among the templates 10, as the template 10 to be used for the imprinting process. The template 10 determined as the template to be used for the imprinting process is carried from the template storage unit 93 to the template stage 81 and placed in accordance with an instruction from the control unit 91.

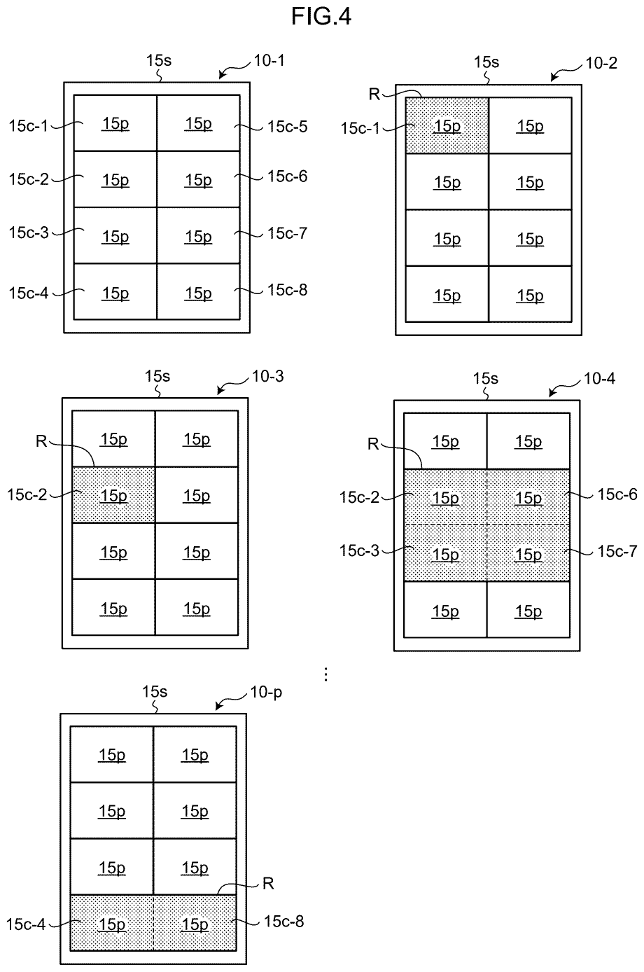

FIG. 4 is a diagram illustrating an example of a layout of a plurality of templates according to the embodiment. In FIG. 4, for convenience, the configuration of the transfer face 15s of each template 10 is illustrated, and illustration of other configurations is omitted.

As illustrated in FIG. 4, the template storage unit 93 stores templates 10-1 to 10-p (p is an integer of 1 or more). For example, an invalid region R that should not be used for pattern formation is set on the transfer face 15s of the template 10-2 to 10-p as some templates of the templates 10-1 to 10-p. The invalid region R is set in one or more units in each of the templates 10-2 to 10-p with the chip pattern region 15c as one unit. The setting position is different for each template 10.

In the template 10-2, the chip pattern region 15c-1 out of the chip pattern regions 15c-1 to 15c-8 is set as the invalid region R. In the template 10-3, the chip pattern region 15c-2 is set as the invalid region R. In the template 10-4, four chip pattern regions 15c-2, 15c-3, 15c-6, and 15c-7 are set as the invalid regions R. In the template 10-p, two chip pattern regions 15c-4 and 15c-8 are set as the invalid regions R.

It is assumed that, for example, the fine pattern 15p of the chip pattern region 15c set as the invalid region R is partly damaged. In this case, even when the template 10 in which the invalid region R is set is pressed against the resist on the substrate 20, the fine pattern 15p is not normally transferred to the chip region 25c corresponding to the chip pattern region 15c set as the invalid region R.

Such a template 10 partly damaged may be a template that cannot be used and that should be replaced because it is damaged by, for example, the imprinting process in manufacturing the semiconductor device so far. The template 10-2 to 10-p in the present embodiment are each assumed to be a template that is partly damaged in the past and should be replaced. The imprinting method of the present embodiment includes reusing a region excluding the damaged portion of each of the template 10-2 to 10-p.

Information about the setting position of the invalid region R is stored in the HDD of the control unit 91 as layout information. The layout information is analyzed by the control unit 91 in order to select the template 10 to be used for the imprinting process from the plurality of templates 10.

Note that the layout illustrated in FIG. 4 is one example, and the present invention is not limited thereto. For example, a plurality of non-adjacent chip pattern regions 15c may be set as the invalid regions R.

Hereinafter, a template to be used for the imprinting process out of the templates 10 may be particularly referred to as a template 10A.

### (Operation Example of Imprint Device)

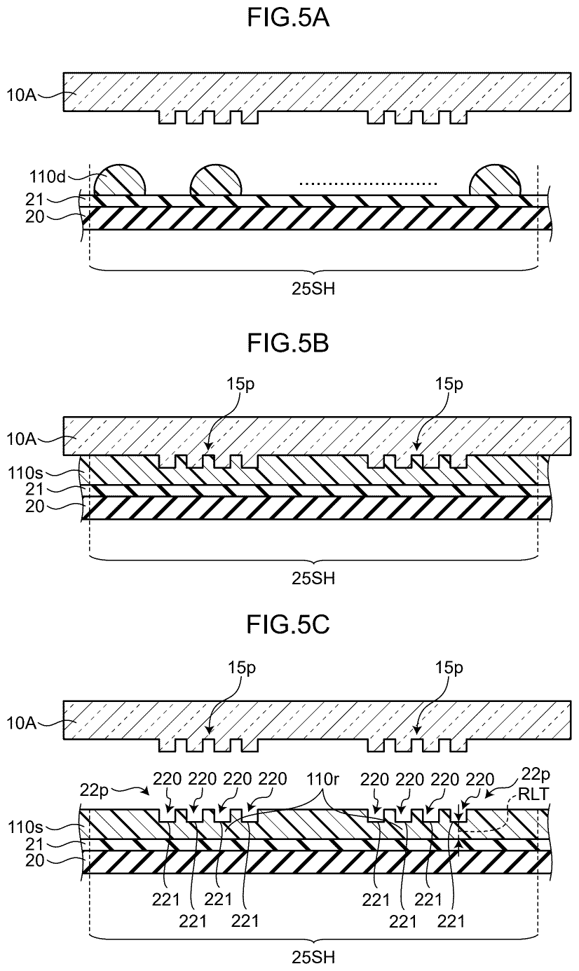

FIGS. 5A to 5C are diagrams for describing an operation example of the imprint device 1 in the imprinting process according to the embodiment.

As illustrated in FIG. 5A, the shot region 25SH to be processed is arranged on the substrate 20 placed on the wafer stage 82. A work film (a film to be processed) 21 is formed on the substrate 20. The work film 21 may be, for example, an insulating film, a conductive film, or a stacked film thereof, and may further include an adhesive film or the like. The droplet 110d is dropped to the shot region 25SH by the liquid dropping device 87 (FIG. 3) of the imprint device 1. The droplet 110d is, for example, a photo-curable resist, and is dropped on the work film 21 in a liquid state before curing. The droplets 110d are dispersed throughout the shot region 25SH.

The dropping amount of one droplet 110d, the dropping number of droplets, the droplet position, and the like are defined in the drop recipe. For example, in the drop recipe, the dropping number of the droplets 110d and the droplet position may be defined such that the droplets 110d are dropped at equal intervals over the entire shot region 25SH. For another example, in the drop recipe, the number of the droplets 110d and the droplet position may be defined such that the dropping number of droplets in a predetermined region in the shot region 25SH is selectively increased. When the dropping number of the droplets 110d increases, the resist amount in a predetermined region in the shot region 25SH increases.

After the droplet 110d is dropped to the shot region 25SH, the template 10A is disposed at a position facing the shot region 25SH in the vertical direction. Alignment is performed by the alignment unit 86 (FIG. 3), and the template 10A is pressed against the droplet 110d.

As illustrated in FIG. 5B, when the template 10A is pressed, the droplets 110d are crushed and spread, and thereby the whole of the droplets 110d are substantially integrated into a resist layer 110s. At this time, the template 10A is held above the substrate 20 with a slight gap from the work film 21. As a result, the uneven portion of the fine pattern 15p provided on the template 10A is gradually filled with part of the resist layer 110s due to the capillary phenomenon.

Subsequently, in a state where the template 10A is pressed, the resist layer 110s is irradiated with light by the light source 89 (FIG. 3) of the imprint device 1 to cure the resist layer 110s. As a result, the fine pattern 15p of the template 10A is transferred to the resist layer 110s.

As illustrated in FIG. 5C, when the template 10A is released, a resist pattern 22p to which the fine pattern 15p has been transferred is formed on the substrate 20.

A resist residual layer 110r generated in the interval between the work film 21 and the template 10A is formed between the work film 21 and a bottom face 221 of a recessed part 220 in the resist pattern 22p. The resist residual layer 110r is part of the resist layer 110s. Hereinafter, the layer thickness of the resist residual layer 110r is referred to as a residual layer thickness RLT. The residual layer thickness RLT is the thickness of the resist residual layer 110r at the bottom face 221 of the recessed part 220 in the resist pattern 22p.

When the formation of the resist pattern 22p is completed in all the shot regions 25SH to be processed provided on the substrate 20, the substrate 20 is carried out from the imprint device 1. After carried out from the imprint device 1, the etching process is performed on the work film 21 by using the resist pattern 22p as a mask.

Hereinafter, the substrate 20 and the work film 21 formed on the substrate 20 may be referred to as a “substrate 20”.

The foreign substance may be placed on the substrate 20 to be imprinted at the stage of passing through a plurality of processes of manufacturing the semiconductor device. When the imprinting process is performed on the substrate 20 on which the foreign substance is placed, the template 10A may be damaged. This is because when the template 10A is pressed against the droplet 110d, the template 10A and the foreign substance come into contact with each other. The template 10 in contact with the foreign substance is deformed so as to bend up and down with the foreign substance as a fulcrum. As the deformation progresses, the template 10A is damaged.

Therefore, as a result of the investigation, the inventors have found that the damage of the template 10A can be suppressed by increasing the layer thickness of the resist between the substrate 20 and the template 10A when the template 10A is pressed, namely, the residual layer thickness RLT. For example, the residual layer thickness RLT can be increased by increasing the dropping number of the droplets 110d to increase the amount of resist on the substrate 20.

However, when the residual layer thickness RLT is increased, the fine pattern 15p of the template 10A is not normally transferred to the resist layer 110s, and formation failure of the resist pattern 22p may occur. This is because the filling property of the resist layer 110s to the uneven portion of the fine pattern 15p is deteriorated.

Capillary force ΔP of resist layer 110s can be used as an index of the filling property of resist layer 110s into the uneven portion of fine pattern 15p. The capillary force ΔP is expressed by ΔP=2γL×Cos θ/R. R is a half value of the residual layer thickness RLT, γL is a surface tension of the resist, and θ is a contact angle of the template 10. As the residual layer thickness RLT increases, the capillary force ΔP decreases. Thus, as the residual layer thickness RLT increases, the filling property of the resist layer 110s into the uneven portion of the fine pattern 15p deteriorates.

As the dropping number of droplets 110d is increased, the time of the entire imprinting process may be longer. As a result, the number of processed substrates 20 per unit time decreases, and as a result, the production amount of the semiconductor device decreases.

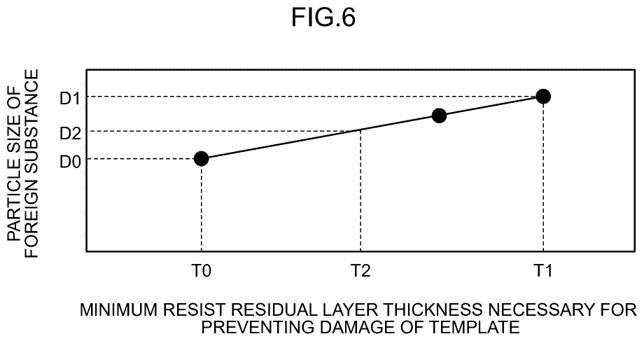

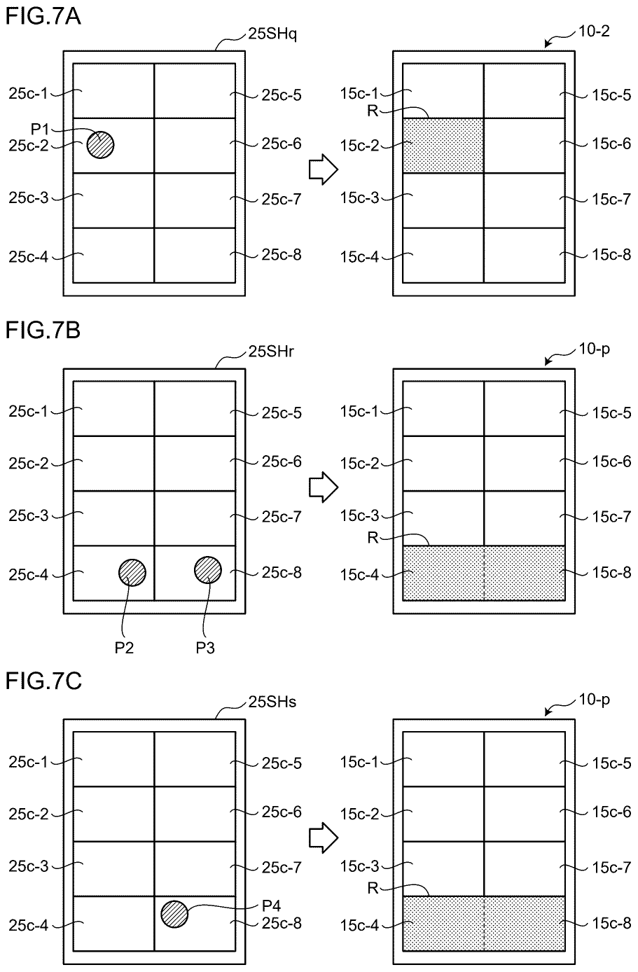

In order to solve the above-described problem while suppressing the damage of the template 10A, the control unit 91 included in the imprint device 1 executes at least one of the first and second control processes. The first and second control processes are performed as part of the imprinting process. Hereinafter, the first and second control processes will be described with reference to FIGS. 6 to 7C.

In executing the first and second control processes, the control unit 91 acquires inspection data of the substrate 20. The inspection data is information in which a particle size, a shot region 25SH where the foreign substance exists, a chip region 25c where the foreign substance exists, and coordinates of the foreign substance on the substrate 20 are correlated with each other for each of the foreign substances. The control unit 91 may acquire the inspection data from the HDD described above, for example, or may acquire the inspection data from the inspection unit 90 without via the HDD, for example.

Based on the inspection data, the control unit 91 determines whether the particle size of the foreign substance existing in each shot region 25SH exceeds D0 as a preset value and exceeds D1 (D1>D0) as a first size. In one example, D0 is 100 nm, and D1 is 1 um.

### (First Control Process)

When determining that the particle size of the foreign substance exceeds D0 and is equal to or smaller than D1, the control unit 91 executes the first control process. The first control process is a process of changing the residual layer thickness RLT in the shot region 25SH where the foreign substance exists in accordance with the particle size of the foreign substance. When executing the first control process, the control unit 91 refers to the correlation data illustrated in FIG. 6. The correlation data in FIG. 6 is obtained by performing an experiment or the like in advance.

FIG. 6 is a diagram illustrating correlation data representing the relationship between the particle size of the foreign substance and the minimum residual layer thickness RLT necessary for suppressing damage of the template. In FIG. 6, the horizontal axis corresponds to the minimum residual layer thickness RLT necessary for suppressing the damage of the template, and the vertical axis corresponds to the particle size of the foreign substance.

As can be seen from FIG. 6, the minimum residual layer thickness RLT necessary for suppressing the damage of the template 10 depends on the particle size of the foreign substance in the range in which the particle size of the foreign substance exceeds D0 and is equal to or less than D1. Thus, the minimum residual layer thickness RLT necessary for suppressing the damage of the template 10 may be small when the particle size of the foreign substance is small, and the minimum residual layer thickness RLT necessary for suppressing the damage of the template 10 is large when the particle size of the foreign substance is large.

The control unit 91 calculates a setting value of the residual layer thickness RLT in the shot region 25SH based on the correlation data and the particle size of the foreign substance acquired from the inspection data.

When, for example, the particle size of the foreign substance existing in the shot region 25SH obtained from the inspection data is D2 (D0<D2≤D1), the control unit 91 calculates T2 corresponding to D2 as a setting value of the residual layer thickness RLT in the shot region 25SH based on the correlation data of FIG. 6.

The control unit 91 generates a drop recipe based on the calculated setting value of the residual layer thickness RLT. Specifically, for example, the control unit 91 calculates the dropping number of the droplets 110d for the residual layer thickness RLT to become T2. Based on the calculation result of the dropping number of the droplets 110d and the coordinates where the foreign substance exists acquired from the inspection data, the control unit 91 defines the dropping number of the droplets 110d and the droplet position in the drop recipe such that the residual layer thickness RLT of a region around the foreign substance becomes T2.

Note that the dropping number of droplets 110d and the droplet position are defined in the drop recipe such that the residual layer thickness RLT becomes T0 (T0<T2) commonly in the shot region 25SH excluding a region around the foreign substance. T0 is the minimum thickness necessary for forming the resist pattern 22p. Hereinafter, T0 may be referred to as a standard residual layer thickness.

The control unit 91 causes the liquid dropping device 87 (FIG. 3) to drop the droplet 110d to the shot region 25SH in accordance with the generated drop recipe. As a result, the residual layer thickness RLT of a region around the foreign substance in the shot region 25SH can be selectively set to T2 (T2>T0), and the residual layer thickness RLT of the other region can be set to T0 that is the standard residual layer thickness.

As described above, according to the first control process, the residual layer thickness RLT of the predetermined region in the shot region 25SH is changed with the particle size of the foreign substance. As a result, it is possible to avoid the residual layer thickness RLT from becoming larger than necessary, and thus, it is possible to suppress the damage of the template 10A while suppressing the formation failure of the resist pattern 22p and the increase in the processing time.

In the above example, the residual layer thickness RLT of a region around the foreign substance in the shot region 25SH is selectively changed, but the present invention is not limited thereto. For example, the residual layer thickness RLT of the entire shot region 25SH where the foreign substance exists may be changed in common.

In a case where the particle size of the foreign substance is D0 or less, the first control process described above is not executed. This is because in a case where the particle size of the foreign substance is D0 or less, damage to the template 10 can be suppressed if the residual layer thickness RLT is T0 that is the standard residual layer thickness.

### (Second Control Process)

When determining that the particle size of the foreign substance exceeds D1 as the first size, the control unit 91 executes the second control process. The second control process is a process of selecting the template 10A to be used for the imprinting process from the templates 10 in accordance with the position of the foreign substance in the shot region 25SH. When executing the second control process, the control unit 91 refers to the layout information of the templates 10 described in FIG. 4.

Based on the chip region 25c where the foreign substance exists acquired from the inspection data and the layout information of the templates 10 stored in the template storage unit 93, the control unit 91 selects, from among the templates 10, a template that the position of the invalid region R set in advance corresponds to the position of the chip region 25c where the foreign substance exists.

FIGS. 7A to 7C are diagrams illustrating the shot region 25SH and the corresponding template 10 side by side according to the embodiment. In each of FIGS. 7A to 7C, an example of the shot region 25SH in which a foreign substance exists is illustrated on the left side of the drawing, and a transfer face 15s of the template 10 corresponding to the shot region 25SH is illustrated on the right side of the drawing.

As illustrated in FIG. 7A, an example is assumed in which a foreign substance P1 (the particle size of the foreign substance P1>D1) exists in the chip region 25c-2 of the shot region 25SHq. In this case, the control unit 91 selects the template 10-2 in which the invalid region R is set in the chip pattern region 15c-2 corresponding to the chip region 25c among the templates 10-1 to 10-p as the template 10A used for the imprinting process.

In addition, for example, as illustrated in FIG. 7B, an example is assumed in which foreign substances P2 and P3 (the particle size of the foreign substance P2, the particle size of the foreign substance P3>D1) exist in the chip regions 25c-4 and 25c-8 of the shot region 25SHr. In this case, the control unit 91 selects, as the template 10A, the template 10-p in which the invalid region R is set in the chip pattern regions 15c-4 and 15c-8 corresponding to the chip regions 25c-4 and 25c-8, respectively, among the templates 10-1 to 10-p.

As described above, in the examples of FIGS. 7A and 7B, the chip region 25c where the foreign substance exists and the chip pattern region 15c set as the invalid region R completely overlap with each other, and the correspondence relationship is 1:1. Thus, in a case where the substrate 20 and the template 10 are aligned, the invalid region R is set to the chip pattern region 15c facing the chip region 25c where the foreign substance exists, and the foreign substance exists in the chip region 25c facing the chip pattern region 15c set as the invalid region R.

Note that the chip region 25c where the foreign substance exists and the chip pattern region 15c set as the invalid region R do not necessarily have a 1:1 correspondence relationship.

For example, as illustrated in FIG. 7C, in a case where a foreign substance P4 exists in the chip region 25c-8 of the shot region 25SHs, the template 10-p in which the chip pattern regions 15c-4 and 15c-8 are set as the invalid region R may be selected as the template 10A. Thus, in a case where the substrate 20 and the template 10 are aligned, the chip region 25c where the foreign substance exists may face any one chip pattern region 15c of the chip pattern regions 15c set as the invalid region R.

When the template 10A selected in this manner is pressed against the droplet 110d, the chip pattern region 15c set as the invalid region R and the chip region 25c where the foreign substance exists vertically face each other. As described above, the fine pattern 15p of the chip pattern region 15c set as the invalid region R is already partly damaged. Therefore, the facing fine pattern 15p of the chip pattern region 15c is damaged again by the foreign substance on the chip region 25c, but this is allowed. On the other hand, the chip pattern region 15c excluding the invalid region R is not newly damaged.

As described above, according to the second control process, the template 10A to be used for the imprinting process is selected from the plurality of templates 10 in accordance with the position of the foreign substance. As a result, it is possible to suppress further damage of the template 10A.

In general, in a case where the particle size of the foreign substance is large, imprinting may not be performed on the shot region 25SH where large foreign substance exists in order to avoid damage of the template 10. According to the second control process, the fine pattern 15p is normally transferred to the chip region 25c facing the chip pattern region 15c excluding the invalid region R. As a result, the number of chips cut out in the process of manufacturing the semiconductor device can be increased as compared with the case where imprinting is not performed on the shot region 25SH.

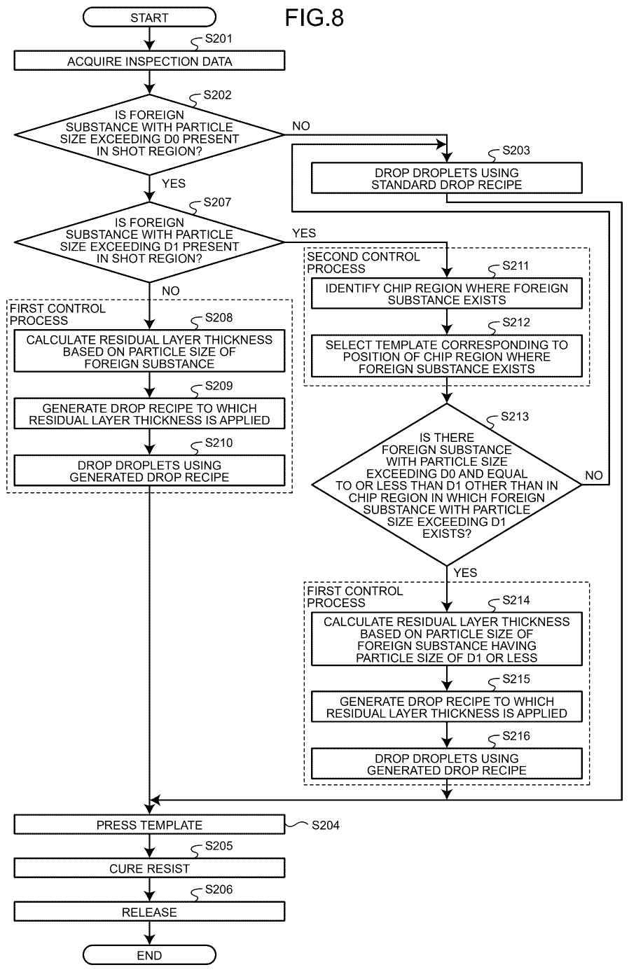

FIG. 8 is a flowchart illustrating a procedure of an imprinting process executed by the imprint device 1 according to the embodiment. The first and second control processes described above are performed as part of the imprinting process.

In the imprint device 1, the processing order of performing the imprinting process on the plurality of shot regions 25SH on the substrate 20 is determined in advance. In the present embodiment, for example, the imprinting process is sequentially performed on the adjacent shot regions 25SH.

Prior to the start of the imprinting process, for example, the template 10-1 is attached to the template stage 81 as an initial state. The template 10-1 is a template in which the invalid region R is not set. When the substrate 20 is disposed on the wafer chuck 82b, the imprinting process starts.

The control unit 91 acquires the inspection data output from the inspection unit 90 (S201).

The control unit 91 determines whether there is a foreign substance having a particle size exceeding D0 in the shot region 25SH to be processed based on the inspection data (S202). D0 is, for example, 100 nm.

When determining that there is no foreign substance having a particle size exceeding D0 in the shot region 25SH (S202: No), the control unit 91 causes the liquid dropping device 87 to drop the droplet 110d to the shot region 25SH in accordance with the standard drop recipe (S203). The standard drop recipe is a drop recipe defined such that the residual layer thickness RLT of the entire shot region 25SH is T0 that is the standard residual layer thickness in common.

On the other hand, in a case where the control unit 91 determines that there is a foreign substance having a particle size exceeding D0 in the shot region 25SH (S202: Yes), the process proceeds to S207.

Next, the control unit 91 determines whether there is a foreign substance having a particle size exceeding D1 in the shot region 25SH to be processed based on the inspection data (S207). D1 is, for example, 1 um.

In a case where the control unit 91 determines that there is no foreign substance having a particle size exceeding D1 in the shot region 25SH (S207: No), the process proceeds to S208. In S208 to S210, the first control process is executed.

As the first control process, the control unit 91 calculates a setting value of the minimum residual layer thickness RLT necessary for suppressing the damage of the template based on the particle size of the foreign substance and the correlation data of FIG. 6 (S208). Next, the control unit 91 generates a drop recipe based on the calculated setting value of the residual layer thickness RLT (S209). The control unit 91 causes the liquid dropping device 87 to drop the droplet 110d to the shot region 25SH in accordance with the generated drop recipe (S210). As a result, the residual layer thickness RLT in the shot region 25SH is changed.

On the other hand, in a case where the control unit 91 determines that there is a foreign substance having a particle size exceeding D1 in the shot region 25SH (S207: Yes), the process proceeds to S211. In S211 to S212, the second control process is executed.

The control unit 91 identifies the position of the chip region 25c where the foreign substance having a particle size exceeding D1 exists (S211). Based on the position of the chip region 25c where the foreign substance having the particle size exceeding D1 exists and the layout information of the templates 10-2 to 10-p, the control unit 91 selects the template 10 in which the position of the invalid region R set in each template 10 and the position of the chip region 25c where the foreign substance exists from among the templates 10-2 to 10-p correspond to each other (S212). In other words, in a case where the substrate 20 and the template 10 are aligned, the control unit 91 selects the template 10 in which the chip region 25c where the foreign substance exists and at least one of the chip pattern regions 15c set as the invalid region R face each other. The selected template 10 is carried from the template storage unit 93 and placed on the template stage 81. The template 10-1 as being in the initial state is returned to the template storage unit 93.

Next, the control unit 91 determines whether there is a foreign substance having a particle size exceeding D0 and equal to or smaller than D1 in the chip region 25c excluding the chip region 25c identified as having a foreign substance having a particle size exceeding D1 in S211 (S213). Thus, the control unit 91 determines whether there is a foreign substance having a particle size of D1 or less in the chip region 25c that does not correspond to the invalid region R of the template 10 selected in step 212.

In a case where the control unit 91 determines that there is no foreign substance having a particle size of greater than D0 and equal to or less than D1 (S213: No), the process proceeds to S203.

On the other hand, in a case where the control unit 91 determines that there is a foreign substance having a particle size of more than D0 and D1 or less (S213: Yes), the process proceeds to S214. In S214 to S216, the first control process described above is executed.

The control unit 91 calculates the setting value of the residual layer thickness RLT based on the particle size of the foreign substance having a particle size of more than D0 and D1 or less and the correlation data of FIG. 6 (S214). The control unit 91 generates a drop recipe to which the calculated setting value of the residual layer thickness RLT is applied (S215). The control unit 91 causes the liquid dropping device 87 to drop the droplet 110d to the shot region 25SH in accordance with the generated drop recipe (S216). Next, the process proceeds to S204 and subsequent steps.

As described above, in a case where the foreign substance having a particle size exceeding D1 and the foreign substance having a particle size not exceeding D1 are present in a mixed manner in the shot region 25SH, two processes of the first and second control processes are executed according to the particle size. That is, the second control process is applied according to the foreign substance having the particle size exceeding D1, and the first control process is applied according to the foreign substance having the particle size not exceeding D1. As described above, by making the first and second control processes applicable to one shot region 25SH, the number of layouts of the templates 10 to be used in the second control process, namely, the number of templates 10 stored in the template storage unit 93 can be reduced.

Next, the control unit 91 causes the stage base 88 to press the template 10A against the droplet 110d (S204). Next, the control unit 91 causes the light source 89 to cure the resist layer 110s (S205). Next, the control unit 91 causes the stage base 88 to release the template 10A from the resist layer 110s (S206). Thus, the imprinting process ends.

### Overview

The imprint device 1 according to the embodiment changes the residual layer thickness RLT based on the particle size of the foreign substance present on the substrate 20.

By setting the residual layer thickness RLT in accordance with the particle size of the foreign substance in this manner, it is possible to avoid the residual layer thickness RLT from becoming larger than necessary. As a result, it is possible to suppress damage to the template 10A while suppressing formation failure of the resist pattern 22p due to insufficient filling into the uneven portion of the template 10A and an increase in processing time due to an increase in the dropping number of droplets of the resist.

In changing the residual layer thickness RLT, the imprint device 1 according to the embodiment calculates the setting value of the residual layer thickness RLT based on the correlation data in which the minimum residual layer thickness RLT necessary for preventing damage of the template 10A is determined for each particle size of the foreign substance. As a result, it is possible to strictly adjust the residual layer thickness RLT to be the minimum according to the particle size of the foreign substance, and thus, it is possible to more effectively suppress formation failure of the resist pattern 22p and an increase in processing time.

The imprint device 1 according to the embodiment further includes a plurality of templates 10 (10-1 to 10-p). In some templates 10 (10-2 to 10-p) of the templates 10, the invalid region R where the fine pattern 15p cannot be formed is set at a different position for each template. In a case where the particle size of the foreign substance exceeds D1, the imprint device 1 selects the template 10 in which the invalid region R corresponds to the position of the foreign substance among the templates 10A in which the invalid region R is set as the template 10A with which the imprinting process is performed. Accordingly, it is possible to prevent the template 10A from being newly damaged.

According to the imprint device 1 of the embodiment, it is possible to perform the imprinting process on the shot region 25SH where the foreign substance exists while suppressing the damage of the template 10A. As a result, the shot regions 25SH in which the resist pattern 22p is formed in at least a part thereof are disposed on substantially the entire face of the substrate 20. As a result, when the etching process is performed on the work film 21 by using the resist pattern 22p as a mask, particles for etching generated by plasma, reaction products between the particles and the work film 21, and the like are uniformly disposed on substantially the entire face of the substrate 20. This makes it possible to suppress deterioration of uniformity of etching.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An imprint device performing an imprinting process, the imprinting process including forming a resin film on a substrate having a plurality of shot regions and forming a pattern by pressing a first template against the resin film, the imprint device comprising:
a computer controlling the imprinting process and being configured to
change a residual layer thickness based on a particle size of a foreign substance on the substrate, the residual layer thickness being a thickness of the resin film at a bottom face of a recessed part in the pattern.

2. The imprint device according to claim 1, wherein the computer is configured to, when changing the residual layer thickness,
calculate a setting value of the residual layer thickness based on a particle size of the foreign substance,
generate a drop recipe based on the setting value, and
form, in accordance with the drop recipe, the resin film on a shot region having the foreign substance.

3. The imprint device according to claim 2, wherein the computer is configured to, when changing the residual layer thickness,
calculate the setting value based on correlation data in which a minimum residual layer thickness is determined for a particle size of the foreign substance.

4. The imprint device according to claim 1, further comprising a plurality of templates including the first template, wherein
each of the plurality of templates includes a transfer face to be pressed against the resin film for each shot region,
each of the transfer face having an invalid region set at a different position for each of the plurality of template, and
the computer is configured to, when a particle size of the foreign substance exceeds a first size,
select an optimal template whose invalid region corresponds to a position of the foreign substance in a shot region when the imprint process is performed.

5. The imprint device according to claim 4, wherein
the shot region on the transfer face includes a plurality of chip pattern regions allowing a plurality of chip regions to be formed, and
the invalid region is set in units of chip pattern regions.

6. The imprint device according to claim 2, wherein the drop recipe is defined to cause, to become the setting value, the residual layer thickness of a region around the foreign substance in the shot region.

7. The imprint device according to claim 2, wherein the drop recipe is defined to cause, to become the setting value, the residual layer thickness of the entire shot region where the foreign substance exists.

8. An imprinting method of forming a pattern by pressing a first template against a resin film, the resin film being formed on a substrate having a plurality of shot regions, the method comprising:
changing a residual layer thickness based on a particle size of a foreign substance on the substrate, the residual layer thickness being a thickness of the resin film at a bottom face of a recessed part in the pattern.

9. The imprinting method according to claim 8, further comprising preparing a plurality of templates including the first template, wherein each of the templates includes a transfer face to form the pattern for each shot region, and an invalid region is set on the transfer face at a different position for each of the plurality of template,
identifying a position of the foreign substance in the shot region based on a particle size of the foreign substance, and
selecting an optical template whose invalid region corresponds to the position of the foreign substance.

10. The imprinting method according to claim 8, wherein the changing the residual layer thickness includes
calculating a setting value of the residual layer thickness based on a particle size of the foreign substance,
generating a drop recipe based on the setting value, and
forming, in accordance with the drop recipe, the resin film on a shot region having the foreign substance.

11. The imprinting method according to claim 10, wherein the changing the residual layer thickness includes
calculating the setting value based on correlation data in which a minimum residual layer thickness is determined for a particle size of the foreign substance.

12. The imprinting method according to claim 9, wherein
the shot region on the transfer face includes a plurality of chip pattern regions allowing a plurality of chip regions to be formed, and
the invalid region is set in units of chip pattern regions.

13. The imprinting method according to claim 10, wherein the drop recipe is defined to cause, to become the setting value, the residual layer thickness of a region around the foreign substance in the shot region.

14. The imprinting method according to claim 10, wherein the drop recipe is defined to cause, to become the setting value, the residual layer thickness of the entire shot region where the foreign substance exists.

15. A method of manufacturing a semiconductor device including an imprinting method, the imprinting method being performed to form a pattern by pressing a first template against a resin film, the resin film being formed on a semiconductor substrate having a plurality of shot regions, the method of manufacturing the semiconductor device comprising:
changing a residual layer thickness based on a particle size of a foreign substance on the semiconductor substrate, the residual layer thickness being a thickness of the resin film at a bottom face of a recessed part in the pattern; and
processing a film by using the resin film having the pattern as a mask.

16. The method of manufacturing the semiconductor device according to claim 15, wherein the changing the residual layer thickness includes
calculating a setting value of the residual layer thickness based on a particle size of the foreign substance,
generating a drop recipe based on the setting value, and
forming, in accordance with the drop recipe, the resin film on a shot region having the foreign substance.

17. The method of manufacturing the semiconductor device according to claim 16, wherein the changing the residual layer thickness includes
calculating the setting value based on correlation data in which a minimum residual layer thickness is determined for a particle size of the foreign substance.

18. The method of manufacturing the semiconductor device according to claim 15, further comprising
preparing a plurality of templates including the first template, wherein each of the templates includes a transfer face to form the pattern for each shot region, and an invalid region is set on the transfer face at a different position for each of the plurality of template,
identifying a position of the foreign substance in the shot region based on a particle size of the foreign substance, and
selecting an optical template whose invalid region corresponds to the position of the foreign substance.

19. The method of manufacturing the semiconductor device according to claim 18, wherein
the shot region on the transfer face includes a plurality of chip pattern regions allowing a plurality of chip regions to be formed, and
the invalid region is set in units of chip pattern regions.

20. The method of manufacturing the semiconductor device according to claim 16, wherein the drop recipe is defined to cause, to become the setting value, the residual layer thickness of a region around the foreign substance in the shot region.
